(19) United States
(12) Patent Application Publication
(10) Pub. No.: US 2012/0125394 A1
(43) Pub. Date: May 24, 2012

(54) Solar Power Plant Conductor Systems, Solar Power Plants, and Junction Assemblies

(76) Inventor: William Clayton Jones, Dillon, MT (US)

(21) Appl. No.: 12/951,999

(22) Filed: Nov. 22, 2010

(51) Int. Cl. H01L 31/05

(52) U.S. Cl. 136/244

(57) ABSTRACT

Solar power plant conductor systems, solar power plants, and junction assemblies are described. According to one aspect, a solar power plant conductor system includes an electrical energy conductor which is configured to electrically conduct electrical energy generated by a plurality of photovoltaic device assemblies of a solar power plant to interface circuitry which is configured to supply the electrical energy externally of the solar power plant and a plurality of junction circuits which are positioned adjacent to a plurality of different longitudinal locations of the electrical energy conductor and which are individually configured to couple at least one of the photovoltaic device assemblies with the electrical energy conductor at one of the respective longitudinal locations of the electrical energy conductor.

### TECHNICAL FIELD

This disclosure relates to title solar power plant conductor systems, solar power plants, and junction assemblies.

### BACKGROUND OF THE DISCLOSURE

The demand for electrical energy has increased in recent decades and this demand is expected to continue to increase. Usage of electrical energy is ubiquitous in almost every aspect of life. For example, businesses, entertainment industries, communications, transportation, etc. are heavily dependent upon electrical energy for fundamental operation. Power distribution and transmission systems or grids conduct electrical energy from generation plants to households, businesses, manufacturing facilities, hospitals, etc. for consumption. Some examples of traditional electrical power generation plants include coal, hydroelectric and nuclear generation plants.

More recently, alternative generation sources of electrical energy have increased in popularity in efforts to help meet the demands of consumers while generating the electrical energy with less impact upon the environment compared with some traditional power generation plants. For example, plants which generate electrical energy from wind or solar energy may produce reduced or substantially no harmful emissions during the generation of electrical energy compared with plants which consume fossil fuels to generate electrical energy.

At least some aspects of the disclosure are directed to electrical energy generation plants including solar plants, conductor systems, and methods of conducting electrical energy within and externally of the generation plants. Additional aspects are disclosed below.

### BRIEF DESCRIPTION OF THE DRAWINGS

Exemplary embodiments of the disclosure are described below with reference to the following accompanying drawings.

FIG. 1 is an illustrative representation of a solar power plant according to one embodiment.

FIG. 2 is an illustrative representation of a solar power plant according to one embodiment.

FIG. 3 is an illustrative presentation of a plurality of photovoltaic device assemblies and a conductor system according to one embodiment.

FIG. 4 is a side view of a junction assembly of a conductor system according to one embodiment.

FIG. 5 is an isometric view of a junction assembly of a conductor system according to one embodiment.

FIG. 6 is an illustrative representation of a coupling device and junction circuitry of a junction assembly according to one embodiment.

### DETAILED DESCRIPTION OF THE DISCLOSURE

This disclosure is submitted in furtherance of the constitutional purposes of the U.S. Patent Laws “to promote the progress of science and useful arts” (Article 1, Section 8).

According to one embodiment, a solar power plant conductor system comprises an electrical energy conductor which is configured to electrically conduct electrical energy generated by a plurality of photovoltaic device assemblies of a solar power plant to interface circuitry which is configured to supply the electrical energy externally of the solar power plant and a plurality of junction circuits which are positioned adjacent to a plurality of different longitudinal locations of the electrical energy conductor and which are individually configured to couple at least one of the photovoltaic device assemblies with the electrical energy conductor at one of the respective longitudinal locations of the electrical energy conductor.

According to an additional embodiment, a solar power plant comprises a plurality of photovoltaic device assemblies which are configured to generate electrical energy as a result of the photovoltaic device assemblies receiving light, a substantially rigid electrical energy conductor which is configured to electrically conduct the electrical energy from the plurality of photovoltaic device assemblies to interface circuitry which is configured to supply the electrical energy externally of the solar power plant, and junction circuitry which is configured to conduct the electrical energy from the photovoltaic device assemblies to the electrical energy conductor.

According to another embodiment, a junction assembly comprises a coupling device which is configured to mechanically couple a plurality of rigid sections with one another to form a portion of a substantially continuous rigid electrical energy conductor which is configured to supply electrical energy generated by a plurality of photovoltaic device assemblies of a solar power plant to interface circuitry which is configured to supply the electrical energy externally of the solar power plant and a junction circuit which is electrically coupled with at least one of the photovoltaic device assemblies and is configured to supply the electrical energy generated by the at least one of the photovoltaic device assemblies to the electrical energy conductor.

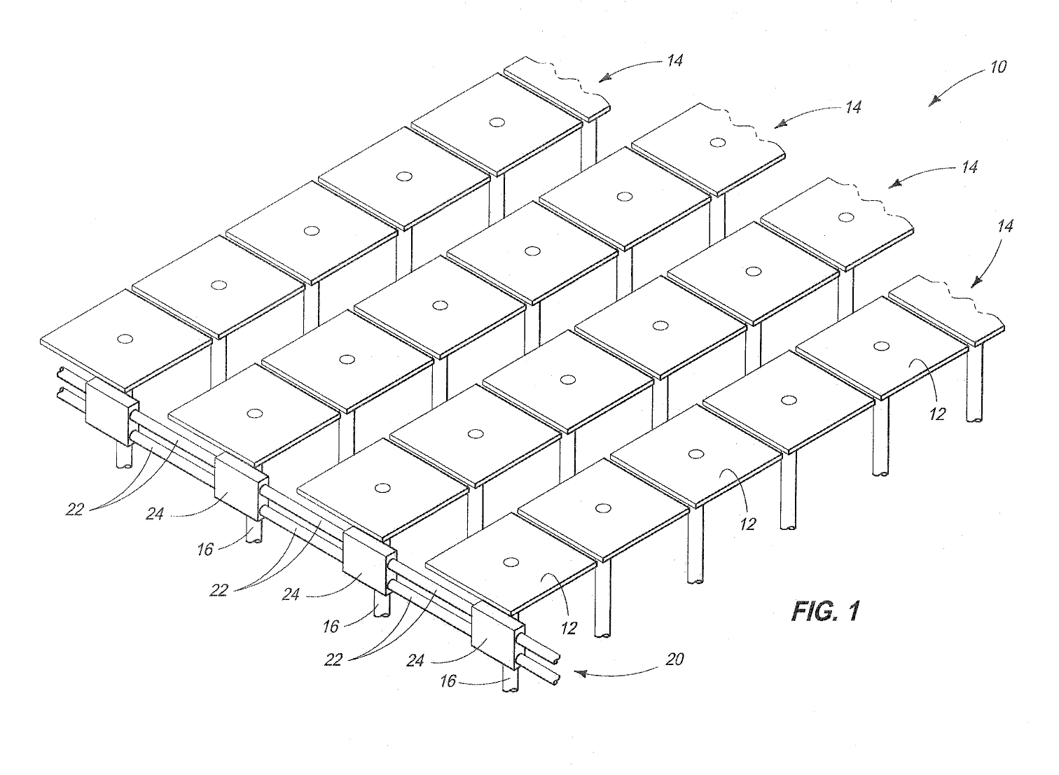

Referring to FIG. 1, a solar power plant 10 is illustrated according to one possible example embodiment. The solar power plant 10 includes a plurality of photovoltaic devices 12 which are configured to generate electrical energy as a result of receiving light.

In one embodiment, the photovoltaic devices 12 are embodied in the form of panels which generate electrical energy at a certain voltage (e.g., 50 DCV). In some implementations, it is desired to provide electrical energy at a system operational voltage which is greater (e.g., 600-1000 VDC) than the voltage of the electrical energy which is generated by the individual photovoltaic devices 12. Accordingly, in one embodiment, the photovoltaic devices 10 may be arranged in a plurality of photovoltaic device assemblies 14 which provide electrical energy at a desired system operational voltage to be provided by the solar power plant 10. In one example, one of the assemblies 14 includes twelve photovoltaic devices 12 which individually generate electrical energy at 50 VDC and are coupled in a series string to provide electrical energy at a voltage of 600 VDC.

The assemblies 14 may be arranged side-by-side in one arrangement which provides the photovoltaic devices 12 in an array, for example, which includes a plurality of columns corresponding to the assemblies 14 of the devices 12 and a plurality of rows corresponding to the devices 12 which are adjacent to one another in the plurality of assemblies 14. This described example embodiment is provided for discussion purposes and other arrangements of the solar power plant 10, photovoltaic devices 12 and assemblies 14 may be provided in other embodiments.

Individual ones of the photovoltaic devices 12 may be supported and elevated above the ground by a support structure which includes a plurality of posts 16 in one embodiment. In addition, a plurality of motors may be coupled with the posts 16 and photovoltaic devices 12 in one implementation and configured to move the photovoltaic devices 12 according to the movement of the sun during the day.

The solar power plant 10 additionally includes a conductor system 20 in the illustrated embodiment. The conductor system 20 is configured to conduct electrical energy generated by the photovoltaic device assemblies 14 to interface circuitry (not shown in FIG. 1) which may thereafter apply the generated electrical energy externally of the solar power plant 10.

In some example embodiments discussed in further detail below, the conductor system 20 includes an electrical energy conductor 22 which is configured to conduct electrical energy generated by the solar power plant 10 and a plurality of junction assemblies.

The electrical energy conductor 22 is implemented as a substantially continuous rigid conductor in one implementation which is discussed in detail below. In one embodiment, the electrical energy conductor 22 is the only conductor which conducts the electrical energy, which is outputted by the photovoltaic device assemblies 14 and received by the conductor 22, to the interface circuitry. The electrical energy conductor 22 is configured to conduct an entirety of the electrical energy generated by the array of photovoltaic devices 12 of the solar power plant 10 to the interface circuitry in one embodiment.

In one embodiment, the electrical energy conductor 22 includes plural conductive members which are configured to conduct direct current electrical energy generated by the photovoltaic devices 12 within the solar power plant 10. In the example configuration of FIG. 1, the conductive members of the conductor 22 correspond to different electrical polarities and one of the conductive members (i.e., the negative or ground member) is arranged elevationally above the other of the conductive members (i.e., the positive member). The conductive members may be arranged differently in other embodiments (e.g., the positive member provided above the negative member, side-by-side, or in other suitable arrangements). The conductive members of the conductor 22 may be implemented as insulated busbars including electrically-insulated positive and negative conductive pipes or tubes in one more specific example arrangement which is discussed in further detail below. Insulated busbars are available from PBP—Preissinger GmbH & Co. KG of Breitenguessbach, Germany.

The conductor system 20 conducts direct current (DC) electrical energy in the above-described example embodiments. Conductor system 20 may be configured to conduct alternating current (AC) electrical energy in other embodiments. For example, assemblies 14 may individually include an inverter which converts DC energy from the photovoltaic devices 12 of the individual assembly 14 to AC energy prior to providing the energy to the conductor system 20 in another embodiment.

As mentioned above in one embodiment, the conductor system 20 also includes a plurality of junction assemblies 24 which are described in detail below in one example configuration. The junction assemblies 24 may include junction circuits which electrically couple small networks of power generation into a larger system. The junction assemblies 24 may couple one or more respective photovoltaic device assemblies 14 to the conductor 22 of the conductor system 20 in the example arrangement. In one embodiment, the conductor 22 couples the photovoltaic device assemblies 14 with one another in parallel and provides the combined electrical energy at an appropriate system operational voltage (e.g., 600-1000 VDC) to the interface circuitry.

In addition, the junction assemblies 24 operate to support the conductor 22 elevated above the ground in one embodiment. For example, the junction assemblies 24 may be coupled with posts 16 to provide a support system which is configured to elevate the conductive members of the conductor 22 above the ground in some implementations. Other support structures, for example including ballasted or racked systems, may be used to support the photovoltaic devices 12 and conductor system 20 in other embodiments. The conductor 22 may be buried below the ground in another embodiment.

One or more of the junction assemblies 24 may be configured to mechanically and electrically couple a plurality of sections of the conductive members of conductor 22 with one another as described in additional detail below. Other configurations for electrically coupling the photovoltaic device assemblies 14 with the electrical energy conductor 22 are possible in other embodiments.

In some embodiments, solar power plant 10 is installed upon a substantially flat surface, such as a field or roof of a building. The photovoltaic devices 14 may be arranged in a horizontal plane in these example embodiments and the conductor system 20 may conduct electricity across the horizontal plane. If the plant 10 is implemented on a roof of a building, the conductor system 20 may also extend down the side of the building in a vertical plane in one embodiment. In another embodiment, the photovoltaic devices 14 of plant 10 may be installed in a vertical plane on the side of a building and the conductor system 20 may extend in a vertical direction in the vertical plane. Other installation embodiments of solar power plant 10 are possible.

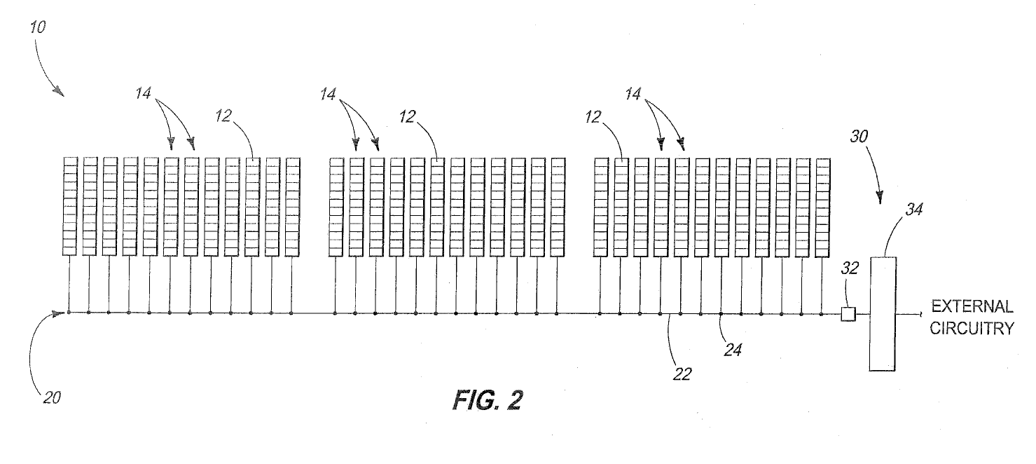

Referring to FIG. 2, an example arrangement of solar power plant 10 is shown. The example solar power plant 10 includes the photovoltaic device assemblies 14 individually including a plurality of photovoltaic devices 12 arranged in series and coupled with the conductor system 20. The individual photovoltaic device assemblies 14 include twelve photovoltaic devices 12 coupled in series with one another to provide an operational voltage of 600 VDC in the illustrated embodiment.

The junction assemblies 24 electrically couple the photovoltaic device assemblies 14 with the conductor system 20. In one embodiment, the junction assemblies 24 are positioned at a plurality of different longitudinal locations of the conductor 22 which are adjacent or proximate to the locations of respective ones of the photovoltaic device assemblies 14 being electrically connected with the conductor 22. In one embodiment, the assemblies 14 are spaced a sufficient distance from one another to collect a maximum amount of sunlight in a day. In one specific example, the junction assemblies 24 are spaced approximately 17.5 feet from one another in an embodiment where the photovoltaic devices 12 are rectangular-shaped with the longer dimensions being parallel with the direction of the conductor 22 and the shorter dimensions being perpendicular to the conductor 22. Two examples of the photovoltaic devices 12 include a 400 W module available from SunPower Corporation and which measures approximately 81.36″×41.18″ and a 280 W Reliathon™ module available from Suntech Power and which measures approximately 77″×42.1″. The junction circuitry of the junction assemblies 24 conducts electrical energy from the respective assemblies 14 to the conductor 22.

In the illustrated example embodiment, the conductor system 20 extends across substantially an entire length of the array of photovoltaic devices 12 which are arranged in the photovoltaic device assemblies 14 in the described embodiment. The junction assemblies 24 are configured to combine the electrical energy generated by one or more of the photovoltaic device assemblies 14 which are located adjacent to the respective assemblies 24 with electrical energy generated by other assemblies 14 at a plurality of respective locations of conductor system 20 which are proximate to the respective assemblies 24 in one embodiment. In one specific example, all of the electrical energy from a given one of the photovoltaic device assemblies 14 is combined with electrical energy of others of the assemblies 14 at only one location of the conductor system 20 which is proximate to the junction assembly 24 which is coupled with the given one of the assemblies 14 in one embodiment.

The electrical energy conductor 22 conducts an entirety of the electrical energy which is generated by the photovoltaic device assemblies 14 of the solar power plant 10 in the depicted example embodiment. In the depicted embodiment, the conductor system 20 transmits the electrical energy to interface circuitry 30 which is configured to conduct the electrical energy externally of the solar power plant 10. More specifically, the conductor system 20 is arranged in the illustrated embodiment to conduct the electrically energy generated by all of the photovoltaic devices 12 to the interface circuitry 30 of the solar power plant 10 including the energy generated by assemblies 14 which are located away from the interface circuitry 30.

In the illustrated example embodiment, the interface circuitry 30 includes a bus breaker 32 and inverter 34. Bus breaker 32 provides an isolation point which is configured to electrically isolate the conductor system 20 and the inverter 34, for example, in the presence of overage conditions. For example, depending upon the configuration of bus breaker 32, the bus breaker 32 may open or couple to ground in the presence of excessive currents upon the conductor system 20.

Bus breaker 32 and inverter 34 may be coupled using conductive wires in one embodiment. The inverter 34 is utilized if the electrical energy is to be output from the solar power plant 10 in the form of alternating current electrical energy. More specifically, the electrical energy generated by the photovoltaic devices 12 is direct current electrical energy which may be converted to alternating current electrical energy (e.g., three-phase AC energy) prior to conduction of the electrical energy to other external circuits, such as a local power system which consumes the energy (e.g., house, hotel, shopping mall, etc.), a utility grid, or other appropriate source which may utilize the electrical energy. The inverter 34 may be omitted if direct current electrical energy is to be outputted from the solar power plant 10 in one embodiment. The inverter 34 may be coupled with external circuitry using wires in one embodiment.

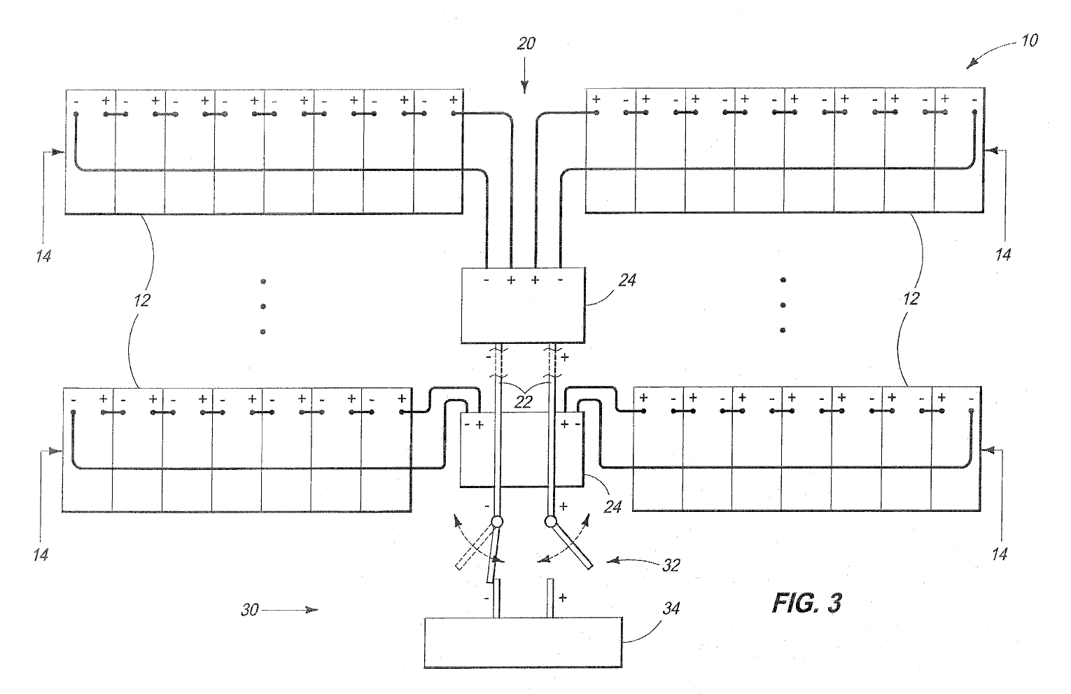

Referring to FIG. 3, additional details of another configuration of an example solar power plant 10 are described. The individual photovoltaic device assemblies 14 include eight photovoltaic devices 12 which are implemented as panels which are coupled with one another in series in the depicted embodiment. Although only four assemblies 14 are shown in FIG. 3, additional assemblies 14 may be provided and coupled with conductor system 20 in another embodiment.

In the example arrangement of the solar power plant 10 of FIG. 3, the assemblies 14 are positioned at opposite sides of the conductor system 20 and a plurality of the assemblies 14 are coupled with individual ones of the junction assemblies 24. Junction circuitry of the individual junction assemblies 24 is configured to electrically couple the photovoltaic devices 12 of the assemblies 14 with the conductor 22 of the conductor system 20 in one embodiment. For example, positive and negative terminals of the assemblies 14 may be coupled with the positive and negative conductive members of the electrical energy conductor 22 in one example embodiment. The conductor 22 conducts the electrical energy to the bus breaker 32 and inverter 34 in the illustrated embodiment.

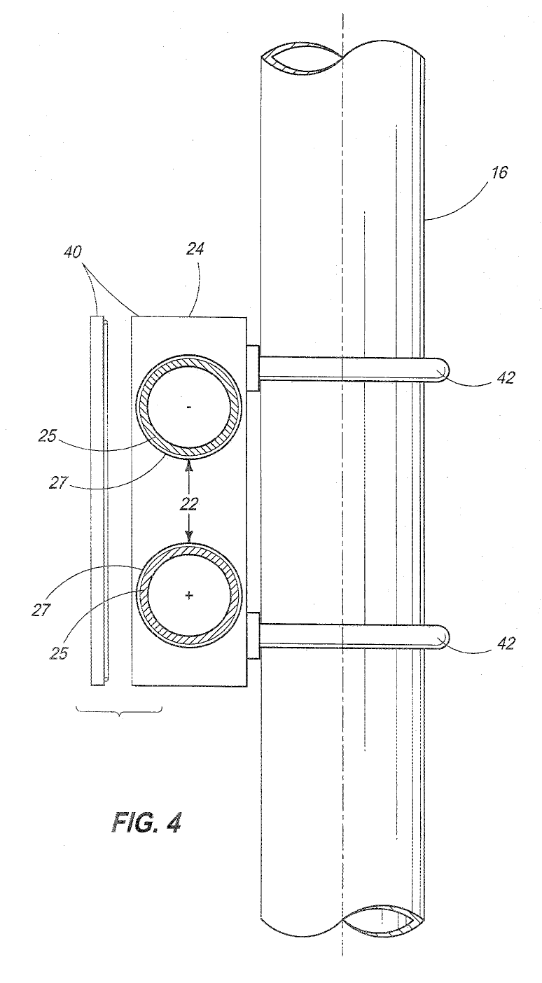

Referring to FIG. 4, one example embodiment of a support structure including a junction assembly 24 is shown. The junction assembly 24 includes a housing 40 which houses junction circuitry (not shown in FIG. 4) and the conductive members of the electrical energy conductor 22 pass through the housing 40. The housing 40 of junction assembly 24 is coupled with a support post 16 using a plurality of U-brackets 42 in one embodiment. The post 16 and junction assembly 24 form a support structure which is configured to support the electrical energy conductor 22 of the conductor system 20 elevationally above the ground in one implementation.

In one embodiment, the housing 40 may include gaskets to protect internal components and circuitry from weather exposure. Furthermore, circuitry may also be provided within the bottom portion of the housing 40 to reduce or prevent water ingress, and additionally, drips loops may be utilized to assist with keeping water from entering the housing 40.

In one example embodiment mentioned above, the conductive members of the electrical energy conductor 22 are implemented as rigid, electrically-insulated conductive members 25. For example, the conductive members 25 may be individually implemented as a pipe or tube which is coated with one or more coatings 27. Example coatings 27 include an appropriate electrical insulation coating (e.g., EPR coating) upon the conductive members 25 with an additional outer coating (e.g., UV resistant PVC coating) which may provide protection of the electrically-insulative coating and conductive members 25 from the sun and elements in one possible implementation.

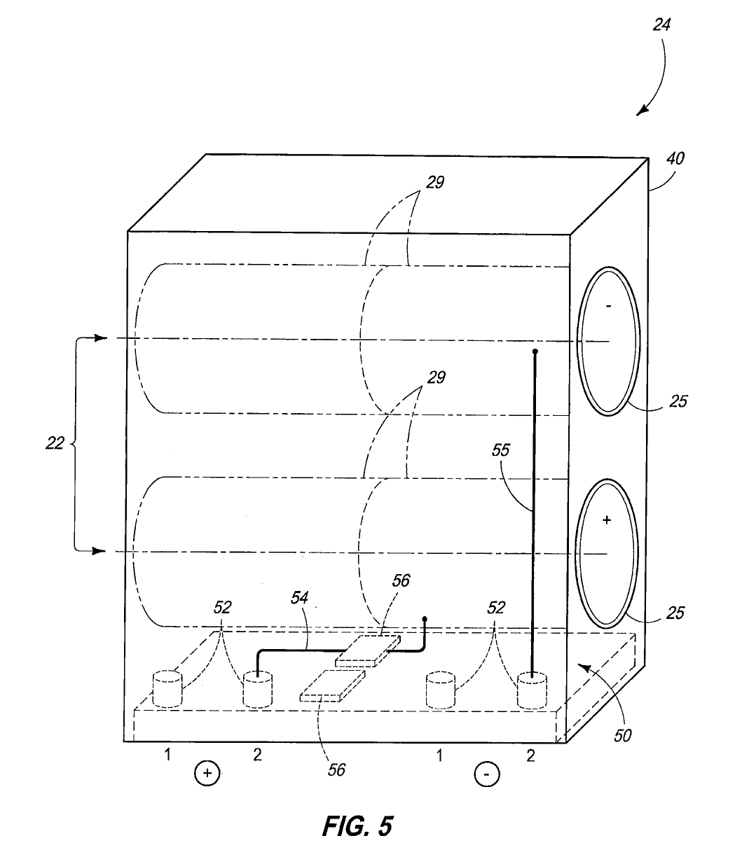

Referring to FIG. 5, additional details of one embodiment of junction assembly 24 are shown. The housing 40 of junction assembly 24 houses junction circuitry 50 which electrically connects one or more of the photovoltaic device assemblies 14 with the electrical energy conductor 22 in one embodiment. In one embodiment, junction circuitry 50 is configured to electrically connect one or more photovoltaic device assemblies 14 which are located proximate to the respective junction assembly 24 with the positive and negative conductive members 25 of the electrical energy conductor 22.

The junction circuitry 50 includes a plurality of connectors 52 which are configured to electrically couple with one or two photovoltaic device assemblies 14 in one example. Other configurations of junction circuitry 50 are possible and additional photovoltaic device assemblies 14 may be coupled with junction circuitry 50 of a junction assembly 24 in other embodiments. In the illustrated embodiment, only one photovoltaic device assembly is coupled with the positive and negative #2 connectors 52 and a photovoltaic device assembly is not coupled with the #1 connectors 52. Example connectors 52 include MC4 connectors or Solarlok connectors available from Tyco Electronics Corporation.

Junction circuitry 50 also includes a wire 54 which couples the positive terminal of the photovoltaic device assembly via a connector 52 with the positive conductive member 25 (i.e., lower in FIG. 5) and a wire 55 couples the negative terminal of the photovoltaic device assembly via a connector 52 with the negative conductive member 25 (i.e., upper in FIG. 5). Wires 54, 55 may individually be #10 AWG 1 kV wire in one embodiment. Other conductors (e.g., solid copper conductor strip) apart from wires 54, 55 may be used in other embodiments. Junction circuitry 50 may also include an appropriate current limiting device 56 (e.g., fuse, breaker, etc.) in series with the wire 54 providing a fused termination point for the wiring of the assembly 14 in one embodiment.

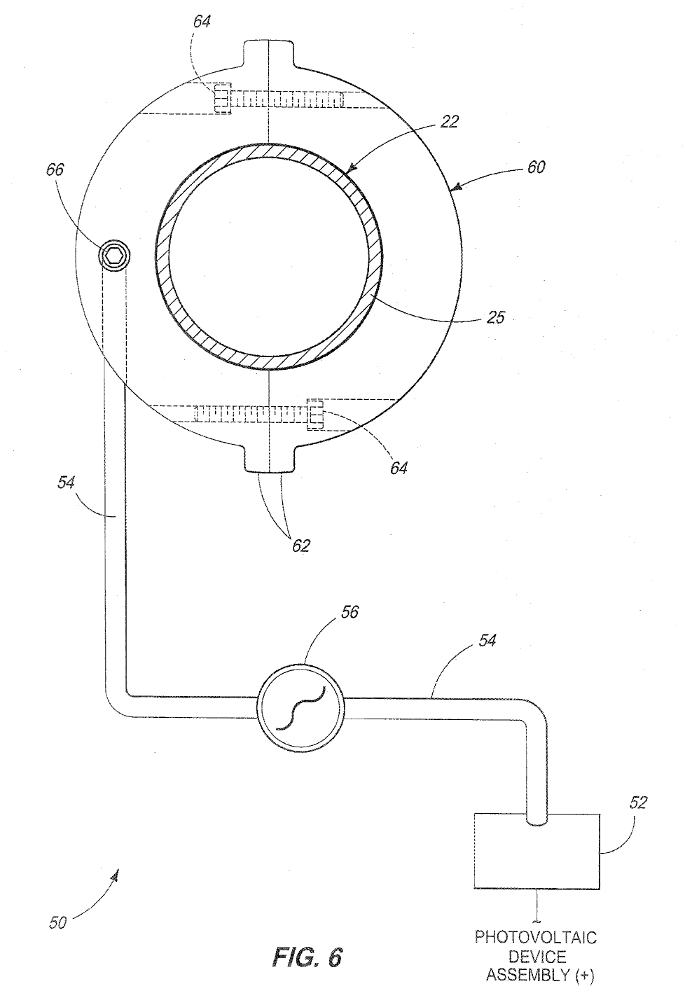

Referring to FIG. 6, one embodiment of a coupling device 60 which may be provided within a junction assembly 24 is shown. In one configuration, the coupling device 60 is embodied as a clamp which includes a plurality of opposing portions 62 which form a cylinder about one of the conductive members 25 of the electrical energy conductor 22. The clamp 22 may be housed within the housing 40 of junction assembly 24 and extend approximately the length of the junction assembly 24 about one of the conductive members 25 in one embodiment.

A plurality of attachment devices 64, such as bolts, may be positioned along the length of the coupling device 60 and configured to mechanically attach the coupling device 60 to the electrical energy conductor 22. In one embodiment, eight attachment devices 64 are provided above and below the conductive member 25 to provide an appropriate mechanical force to support and constrain the conductive member 25. Attachment devices 64 may include alien head type fasteners in one embodiment to reduce the installed size.

The opposing portions 62 of the coupling device 60 may be electrically conductive and the electrical insulation 27 may be removed from portions of the conductive members 25 within the junction assembly 24 providing electrical contact between the coupling device 60 and the conductive members 25. In one embodiment, the coupling device 60 is a compatible aluminum alloy to reduce or avoid galvanic corrosion of the conductive members 25 and coupling device 60.

Furthermore, one of the portions 62 may include a termination 66 which is configured to electrically connect with wire 54 of the junction circuitry 50. Accordingly, in one embodiment, electrical energy which is generated by a photovoltaic device assembly 14 may be received by connector 52 and applied to the electrical energy conductor 22 using the wire 54, fuse 56 and coupling device 60. The illustrated example coupling device 60 is coupled with the positive conductive member 25 and junction assembly 24 may also include another coupling device 60 to be coupled with the negative conductive member 25.

As mentioned above, the electrical energy conductor 22 includes rigid, insulated conductive members 25 (e.g., insulated pipe or tube) in one embodiment. In one configuration, the electrical energy conductor 22 includes a plurality of rigid sections which may be electrically coupled with one another to form the conductive members 25. In one implementation mentioned above, the conductive members 25 of the electrical energy conductor 22 may be supported above the ground by the coupling devices 60 of the junction assemblies 24 which may be coupled with posts 16. Furthermore, one or more of the junction assemblies 24 may be configured to mechanically and electrically spice, join and couple the opposing ends of two adjacent sections of the conductive members 25 for continuity therebetween and to form substantially continuous conductive members 25 of conductor 25. The individual sections of the conductive members 25 may be 20 feet of 2″ 6063 T6 Schedule 40 aluminum tube with an appropriate external electrically-insulative coating, for example, at least greater than the system voltage plus a safety margin. In some implementations, the conductor 22 may extend hundreds of feet (e.g., 400-500 feet in one example) between opposite ends of the solar power plant.

For example, referring again to FIG. 5, two opposing ends of adjacent sections 29 of the conductive members 25 may be received within the junction assembly 24. Two coupling devices 60 (not shown in FIG. 5) may be configured to mechanically and electrically couple the sections 29 together for each of the conductive members 25. The coupling devices 60 for the conductive members 25 are also mechanically coupled with the junction assembly 24 and brackets 42 and configured to support the conductive members 25 of the conductor 22 elevationally above the ground in one embodiment. In one embodiment, the sections 29 of the conductive members 25 have lengths which exceed the spacing between adjacent ones of the photovoltaic device assemblies 14, and accordingly, the coupling devices 60 of some of the junction assemblies 24 are individually only coupled with one of the sections 29 of the conductive members 25 which pass through the junction assemblies 24.

In one embodiment, one or more expansion joints may be provided within the conductive members 25 of the conductor 22 to allow for thermal expansion and contraction of the conductor 22 due to environmental temperature fluctuations and conduction of electrical energy. In one embodiment, the expansion joints may be located externally of the junction assemblies 24 and between adjacent ones of the junction assemblies 24. The expansion joints may individually include a space provided between ends of adjacent sections of the conductive members 25 and a wire may be provided to conduct the electrical energy between the sections. In another embodiment, a z-shaped plate of an appropriate conductive material (e.g., metal, aluminum) may be welded between the ends of the adjacent sections of the conductive members 25 to form an expansion joint. Other configurations of expansion joints are possible in other embodiments.

At least some of the aspects of the disclosure provide conductor systems which efficiently collect and conduct the generated electrical energy with reduced losses compared with the some conventional designs. The use of conductive members of the conductors which are configured to be substantially rigid in accordance with some of the described embodiments are self-supporting and additional supporting hardware, such as a cable tray which is used in some conventional arrangements to support flexible wires, may be omitted in some implementations. Furthermore, the utilization of electrically-insulated conductors provides safety without burying the conductors in some embodiments. The utilization of the conductor system described according to example embodiments of the disclosure may reduce the footage of wire by approximately 70% in some implementations compared with conventional arrangements which utilize combiner and recombine boxes. The reduction in wire provided by the conductor system of some embodiments of the disclosure may also provide a reduction in failure points compared with some conventional designs.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

Further, aspects herein have been presented for guidance in construction and/or operation of illustrative embodiments of the disclosure. Applicant(s) hereof consider these described illustrative embodiments to also include, disclose and describe further inventive aspects in addition to those explicitly disclosed. For example, the additional inventive aspects may include less, more and/or alternative features than those described in the illustrative embodiments. In more specific examples, Applicants consider the disclosure to include, disclose and describe methods which include less, more and/or alternative steps than those methods explicitly disclosed as well as apparatus which includes less, more and/or alternative structure than the explicitly disclosed structure.

What is claimed is:

1. A solar power plant conductor system comprising:
an electrical energy conductor which is configured to electrically conduct electrical energy generated by a plurality of photovoltaic device assemblies of a solar power plant to interface circuitry which is configured to supply the electrical energy externally of the solar power plant; and
a plurality of junction circuits which are positioned adjacent to a plurality of different longitudinal locations of the electrical energy conductor and which are individually configured to couple at least one of the photovoltaic device assemblies with the electrical energy conductor at one of the respective longitudinal locations of the electrical energy conductor.

2. The system of claim 1 wherein an individual one of the junction circuits is configured to couple the respective at least one of the photovoltaic device assemblies with the respective one of the different longitudinal locations of the electrical energy conductor which is adjacent to the individual one of the junction circuits and the respective at least one of the photovoltaic device assemblies.

3. The system of claim 1 wherein the electrical energy conductor is configured to electrically conduct an entirety of the electrical energy generated by all of the photovoltaic device assemblies of the solar power plant to the interface circuitry.

4. The system of claim 1 wherein the electrical energy conductor is a substantially continuous rigid electrical energy conductor.

5. The system of claim 4 wherein the junction circuits are coupled with respective ones of a plurality of junction assemblies, and at least some of the junction assemblies include a coupling device which is configured to mechanically couple a plurality of different rigid sections of a conductive member of the electrical energy conductor with one another.

6. The system of claim 4 wherein the conductive member comprises an insulated bus bar.

7. The system of claim 1 wherein the electrical energy conductor conducts the electrical energy across substantially an entire length of the solar plant array.

8. The system of claim 1 wherein the electrical energy generated by one of the photovoltaic device assemblies is combined with electrical energy generated by others of the photovoltaic device assemblies at only one of the different longitudinal locations of the electrical energy conductor.

9. A solar power plant comprising:
a plurality of photovoltaic device assemblies which are configured to generate electrical energy as a result of the photovoltaic device assemblies receiving light;
a substantially rigid electrical energy conductor which is configured to electrically conduct the electrical energy from the plurality of photovoltaic device assemblies to interface circuitry which is configured to supply the electrical energy externally of the solar power plant; and
junction circuitry which is configured to conduct the electrical energy from the photovoltaic device assemblies to the electrical energy conductor.

10. The plant according to claim 9 wherein the junction circuitry comprises a plurality of junction circuits which are configured to supply the electrical energy from the photovoltaic device assemblies to the electrical energy conductor at a plurality of different longitudinal locations of the electrical energy conductor.

11. The plant according to claim 9 wherein the electrical energy conductor comprises a plurality of substantially continuous conductive members.

12. The plant according to claim 11 further comprising a plurality of junction assemblies which comprise a plurality of respective junction circuits of the junction circuitry, and at least some of the junction assemblies individually include a coupling device which is configured to mechanically couple a plurality of different rigid sections of the conductive members with one another to form the substantially continuous conductive members.

13. The plant according to claim 12 wherein the coupling devices are electrically conductive and the coupling devices are electrically coupled with respective ones of the junction circuits.

14. The plant according to claim 9 wherein the electrical energy conductor is the only conductor which conducts the electrical energy generated by the photovoltaic device assemblies of the solar plant array intermediate the junction circuitry and the interface circuitry.

15. The plant according to claim 9 further comprising a support structure configured to support the photovoltaic device assemblies elevated above the ground, and wherein the substantially rigid electrical energy conductor is elevated above the ground by the support structure.

16. A junction assembly comprising:
a coupling device which is configured to mechanically couple a plurality of rigid sections with one another to form a portion of a substantially continuous rigid electrical energy conductor which is configured to supply electrical energy generated by a plurality of photovoltaic device assemblies of a solar power plant to interface circuitry which is configured to supply the electrical energy externally of the solar power plant; and
a junction circuit which is electrically coupled with at least one of the photovoltaic device assemblies and is configured to supply the electrical energy generated by the at least one of the photovoltaic device assemblies to the electrical energy conductor.

17. The assembly of claim 16 wherein the junction assembly and the at least one of the photovoltaic device assemblies are positioned adjacent to one of a plurality of different longitudinal locations of the electrical energy conductor, and the junction circuit is configured to supply the electrical energy generated by the at least one of the photovoltaic device assemblies located adjacent to the one of the longitudinal locations to the electrical energy conductor at the one of the longitudinal locations of the electrical energy conductor.

18. The assembly of claim 17 wherein the junction circuit combines an entirety of the electrical energy generated by the at least one of the photovoltaic device assemblies with an entirety of the electrical energy upon the electrical energy conductor.

19. The assembly of claim 16 wherein the coupling device is electrically conductive and the junction circuit is electrically coupled with the coupling device.

20. The assembly of claim 16 wherein the coupling device is configured to support the portion of the electrical energy conductor above the ground.
